(19) United States
(12) Patent Application Publication
(10) Pub. No.: US 2016/0078959 A1
(43) Pub. Date: Mar. 17, 2016

(54) NON-VOLATILE SEMICONDUCTOR MEMORY DEVICE

(71) Applicant: KABUSHIKI KAISHA TOSHIBA, Tokyo (JP)

(72) Inventors: Sanad BUSHNAQ, Yokohama Kanagawa (JP); Masanobu SHIRAKAWA, Chigasaki Kanagawa (JP); Yuya SUZUKI, Iwaki Fukushima (JP)

(21) Appl. No.: 14/634,701

(22) Filed: Feb. 27, 2015

(30) Foreign Application Priority Data
Sep. 12, 2014 (JP) 2014-186603

(51) Int. Cl. G11C 16/32; G11C 16/24; G11C 16/26; G11C 16/10

(52) U.S. Cl. CPC G11C 16/32; G11C 16/10; G11C 16/24; G11C 16/26

(57) ABSTRACT

A non-volatile semiconductor memory device includes a plurality of memory cells including a first memory cell and a second memory cell stacked above the first memory cell, a plurality of word lines including first and second word lines connected to first and second memory cells, respectively, a driver circuit connected to gates of the memory cells to supply voltages of different levels to the gates of the memory cells, and a control circuit configured to control the driver circuit to apply, during a reading operation on a selected memory cell, a first voltage to other, non-selected memory cells at a first timing and a second voltage to the selected memory cell at a second timing that is after a time period after the first timing. The time period when the first memory cell is the selected memory cell is less than the time period when the second memory cell is the selected memory cell.

### CROSS-REFERENCE TO RELATED APPLICATION

This application is based upon and claims the benefit of priority from Japanese Patent Application No. 2014-186603, filed Sep. 12, 2014, the entire contents of which are incorporated herein by reference.

### FIELD

Exemplary embodiments described herein relate to a non-volatile semiconductor memory device.

### BACKGROUND

In recent years, stacked semiconductor memories (BiCS: Bit Cost Scalable Flash Memories) in which memory cells are stacked have been developed. The BiCS is able to realize a low-cost and large-capacity semiconductor memory.

### DESCRIPTION OF THE DRAWINGS

FIG. 1 is an entire configuration example illustrating a non-volatile semiconductor memory device according to a first embodiment.

FIG. 2 is a circuit diagram illustrating a driver circuit according to the first embodiment.

FIG. 3 is a concept diagram illustrating a control circuit according to the first embodiment.

FIG. 4 is a circuit diagram illustrating a sense amplifier according to the first embodiment.

FIG. 5 is a circuit diagram illustrating the sense amplifier according to the first embodiment.

FIG. 6 is a cross-sectional view illustrating a memory cell array according to the first embodiment.

FIG. 7 is a concept diagram illustrating the characteristics of a memory cell according to the first embodiment.

FIG. 8 is a timing diagram illustrating a reading operation performed on an upper-layer word line according to the first embodiment.

FIG. 9 is a timing diagram illustrating a reading operation performed on a lower-layer word line according to the first embodiment.

FIGS. 10A to 10D are concept diagrams illustrating a threshold distribution of the memory cell according to the first embodiment.

FIG. 11 is a timing diagram illustrating a reading operation performed on an upper-layer word line according to a first modification example.

FIG. 12 is a timing diagram illustrating a reading operation performed on a lower-layer word line according to the first modification example.

FIG. 13 is a timing diagram illustrating a rise in voltage in a non-select word line according to a second modification example.

FIG. 14 is a timing diagram illustrating a reading operation according to a third modification example.

FIG. 15 is a timing diagram illustrating a reading operation according to the third modification example.

FIG. 16 is a timing diagram illustrating a write operation according to a second embodiment.

FIG. 17 is a timing diagram illustrating a write operation according to the second embodiment.

FIG. 18 is a timing diagram illustrating a write operation according to a fourth modification example.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to limit the scope of the invention. As used herein, the singular forms “a,” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” in accordance with the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A non-volatile semiconductor memory device which is capable of shortening a reading time is provided.

According to an embodiment, a non-volatile semiconductor memory device including: a plurality of memory cells including a first memory cell and a second memory cell stacked above the first memory cell, a plurality of word lines including first and second word lines connected to first and second memory cells, respectively, a driver circuit connected to gates of the memory cells to supply voltages of different levels to the gates of the memory cells, and a control circuit configured to control the driver circuit to supply, during a reading operation on a selected memory cell, a first voltage to other, non-selected memory cells at a first timing and a second voltage to the selected memory cell at a second timing that is after a time period after the first timing. The time period when the first memory cell is the selected memory cell is less than the time period when the second memory cell is the selected memory cell.

Hereinafter, the present embodiments will be described with reference to the accompanying drawings. In the description, common components are denoted by common reference numerals and signs throughout all the drawings.

### First Embodiment

### 1. Entire Configuration Example

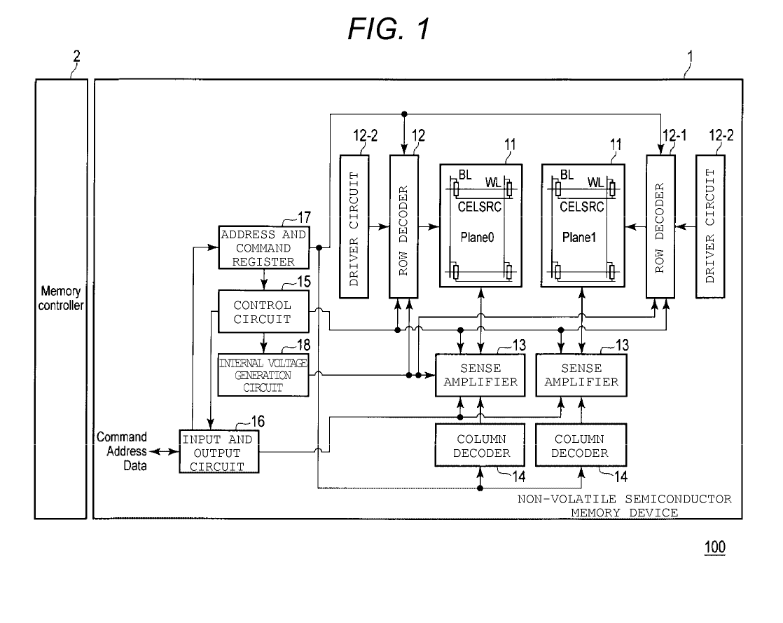

The entire configuration of a semiconductor device according to a first embodiment will be described with reference to FIG. 1. A memory system includes a non-volatile semiconductor memory device 1 and a memory controller 2 that controls the non-volatile semiconductor memory device 1.

As shown in FIG. 1, the non-volatile semiconductor memory device 1 according to the first embodiment includes a memory cell array 11, a row decoder 12-1, a driver circuit 12-2, a sense amplifier 13, a column decoder 14, a control circuit 15, an input and output circuit 16, an address and command register 17, and an internal voltage generation circuit 18.

1.1 Memory Cell Array 11

As shown in FIG. 1, the memory cell array 11 includes, for example, a plane P0 and a plane P1 (denoted by Plane0 and Plane1 in FIG. 1).

The plane P0 and the plane P1 include a plurality of memory strings MS, and a bit line BL, a word line WL, and a source line CELSRC are electrically connected to the memory strings MS.

As described later, the memory string MS includes a plurality of memory cells MC which are connected to each other in series, and the above-mentioned word line WL is connected to a control gate CG configuring the memory cell MC.

Here, a case in which the plane P0 and the plane P1 are included is described as an example, and there is no limit to the number of planes P included in the memory cell array 11. Meanwhile, when the plane P0 and the plane P1 are not distinguished from each other, these planes are simply described as the plane P.

1.2 Row Decoder 12-1 and Driver 12-2

A row decoder 12-1 (hereinafter, sometimes called a block decoder 12-1) and a driver 12-2 will be described below.

The row decoder 12-1 decodes a block address signal or the like which is input from the address and command register 17, and activates a block BLK to be selected in accordance with the decoding result.

Next, the row decoder 12-1 supplies a voltage which is generated by the driver 12-2 to the word line WL within the selection block BLK.

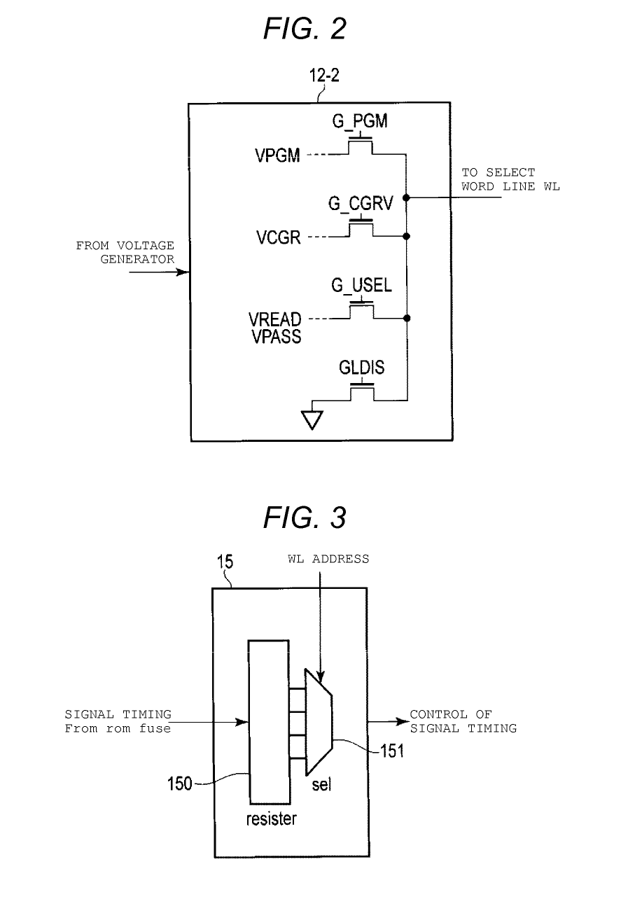

The driver 12-2 will be described with reference to FIG. 2.

As shown in FIG. 2, the driver 12-2 includes a MOS transistor that transfers a voltage VPGM, a voltage VCGR, a voltage VPASS, and a voltage VREAD to a predetermined word line WL.

When the control circuit 15 sets the voltage level of a signal G_PGM to “H”, the row decoder 12 supplies the voltage VPGM to the select word line WL. The same is true of the voltage VCGR, the voltage VPASS, the voltage VREAD, and a ground potential.

1.3 Control Circuit 15

The control circuit 15 controls an operation of the entire non-volatile semiconductor memory device 1. That is, an operation sequence in a reading operation of data is executed based on a control signal, a command CMD, and an address ADD which are supplied from the address and command register 17.

The control circuit 15 controls an operation of each circuit block included in the non-volatile semiconductor memory device 1 in order to execute this sequence.

For example, the control circuit 15 performs control so that the internal voltage generation circuit 18 generates a predetermined voltage, and controls a predetermined timing for outputting the predetermined voltage to the word line WL or the bit line BL through the row decoder 12 and the sense amplifier 13.

In addition, the control circuit 15 includes a register 150 and a selector 151, which are shown in FIG. 3. Meanwhile, the register 150 and the selector 151 are caused to function in a first modification example described later.

1.3.1 Register 150

The register 150 holds, for example, a timing T (hereinafter, sometimes called information) for changing the voltage level of a signal in accordance with a selected word line address which is received from the memory controller 2. When the non-volatile semiconductor memory device 1 is turned-on, this information is read from, for example, a ROM FUSE which is provided in the inside of the memory cell array 11, and then is stored in the register 150.

Meanwhile, the ROM FUSE is not limited to the inside of the memory cell array 11. For example, the ROM FUSE may be provided in the inside of the register within the non-volatile semiconductor memory device 1.

1.3.2 Selector 151

When a word line WL address is received from the address and command register 17, the selector 151 selects the timing T in accordance with this word line WL address.

Specifically, when an address indicating an upper-layer word line WL is received, the selector 151 selects a timing T1 (hereinafter, referred to as a first mode).

In addition, when an address indicating a lower-layer word line WL is received, the selector 151 selects a timing T2 (hereinafter, referred to as a second mode).

In this manner, the control circuit 15 outputs the timing T selected by the selector 151 to a MOS transistor in the sense amplifier 13.

1.4 Sense Amplifier 13

The sense amplifier 13 has a function of reading data of the memory cell MC, and writing the data to the memory cell MC. When the non-volatile semiconductor memory device 1 receives a command CMD (00H), an address ADD, and a command CMD (30H) for loading a reading operation which are transferred from the memory controller 2, the sense amplifier 13 performs reading from the memory cell MC of a selected page at a timing according to an instruction from the control circuit 15.

Hereinafter, the configurations of two types of sense amplifiers 13 will be described. Data detection methods (current detection and voltage detection) and operations are different from each other in accordance with a difference between the configurations.

1.4.1 Details of Sense Amplifier 13 (Current Detection)

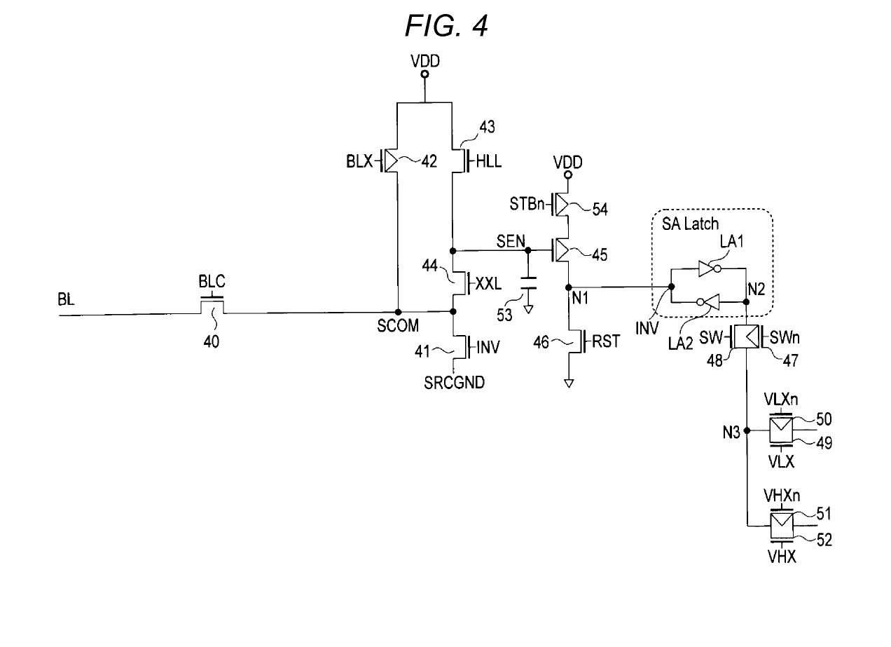

The configuration of the sense amplifier 13 that senses a current flowing in the bit line BL and reads data will be described with reference to FIG. 4. The sense amplifier 13 may read data simultaneously from all the bit lines BL. As shown in the drawing, the sense amplifier 13 includes n-channel type MOS transistors 40, 41, 43, 44, 46, 48, 49, and 52, p-channel type MOS transistors 42, 45, 47, 50, 51, and 54, a capacitor element 53, and an SA Latch.

One end of the MOS transistor 40 is connected to the bit line, and the other end is connected to SCOM. The gate is supplied with a signal BLC.

One end of the MOS transistor 41 is connected to the SCOM, and the other end is grounded. The gate is supplied with a signal INV.

One end of the MOS transistor 42 is connected to the SCOM, and the other end is supplied with a voltage VDD. The gate is supplied with a signal BLX.

In addition, one end of the MOS transistor 43 is connected to a SEN node, and the other end is supplied with the voltage VDD. The gate is supplied with a signal HLL.

Further, one end of the MOS transistor 44 is supplied with the SCOM, and the other end is connected to the SEN node. The gate is supplied with a signal XXL.

In addition, one electrode of the capacitor element 53 is connected to the SEN node, and the other electrode is grounded.

One end of the MOS transistor 45 is connected to a node N1, and the gate is connected to the SEN node. Meanwhile, this node N1 is also INV.

One end of the MOS transistor 46 is connected to the node N1, and the other end is grounded. The gate is supplied with a signal RST.

One end of the MOS transistor 54 is supplied with the voltage VDD, and the gate is supplied with a signal STBn.

The SA Latch includes a latch LA1 and a latch LA2.

The node N1 is connected to the input port of the latch LA1 and the output port of the latch LA2, and the output port of the latch LA1 and the input port of the latch LA2 are connected to a node N2. Meanwhile, this node N2 is also LAT. In addition, the SA Latch holds a value in the node N1.

The MOS transistors 47 and 48 may electrically connect the node N2 and a node N3. That is, one end of each of the MOS transistors 47 and 48 is connected to the node N2, and the other end is connected to the node N3.

The voltage levels of a signal SW and a signal SWn are set to “L” and “H” in a complementary manner, and thus the MOS transistors 47 and 48 electrically connect the nodes N2 and N3. That is, these transistors function as a switch.

In addition, the same is true of a switch which is configured by a combination of the MOS transistors 49 and 50 and a switch which is configured by a combination of the MOS transistors 51 and 52, and thus the description thereof will not be given.

1.4.2 Details of Sense Amplifier 13 (Voltage Detection)

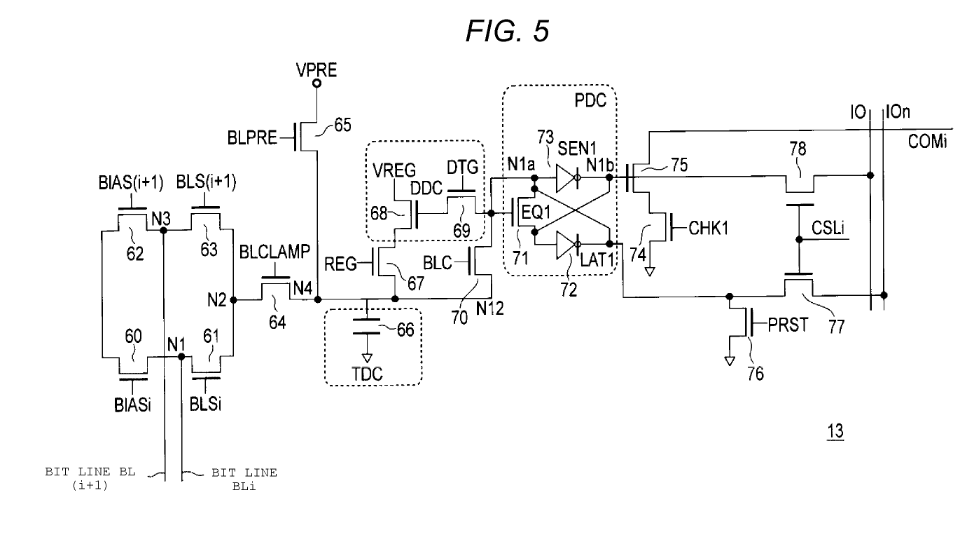

Next, the sense amplifier 13 that read data by detecting a voltage value of the bit line BL after discharging will be described with reference to FIG. 5. The sense amplifier 13 reads a bit line BL voltage alternately in an even-odd manner.

That is, the sense amplifier 13 of a second configuration in which reading and writing are collectively performed on n/2 bit lines BL out of n bit lines BL.

As shown in FIG. 5, the sense amplifier 13 includes n-channel MOS transistors 60 to 65, 67 to 71, 74 to 78, a capacitor element 66, and inverters 72 and 73.

One end of the MOS transistor 60 is connected to the node N1, and the gate is supplied with a signal BIASi.

One end of the MOS transistor 61 is connected to one end of the MOS transistor 60 through the node N1, and the other end is connected to the node N2. The gate is supplied with a signal BLSi.

One end of the MOS transistor 62 is connected to the node N3, and the gate is supplied with a signal BIAS (i+1).

One end of the MOS transistor 63 is connected to one end of the MOS transistor 62 through the node 3, and the other end is connected to the node N2. The gate is supplied with a signal BLS (i+1).

In addition, an even bit line BLi is connected to the node N1, and an odd bit line BL (i+1) is connected to the node N3.

That is, when the MOS transistor 61 is turned on, the even bit line BLi and the sense amplifier 13 are electrically connected to each other. On the other hand, when the MOS transistor 63 is turned on, the odd bit line BL (i+1) and the sense amplifier 13 are electrically connected to each other.

In this manner, the sense amplifier 13 and any of the even-odd bit lines BL are selectively connected to each other by turning on the MOS transistor.

One end of the MOS transistor 64 is connected to the node N2, and the other end is connected to a node N4. The gate is supplied with a signal BLCLAMP. The control circuit 15 controls a timing at which the voltage level of this signal BLCLAMP is set to “H”. This specific status will be described with reference to timing diagrams described later.

One end of the MOS transistor 65 is connected to the node N4, and the other end is supplied with a voltage VPRE. The gate is supplied with a signal BLPRE.

The precharging of the bit line BL is performed through the MOS transistor 65.

One electrode of a capacitor element 66 is connected to the node N4, and the other electrode serves as a ground potential.

One end of the MOS transistor 67 is connected to the node N4, and the gate is supplied with a signal REG.

One end of the MOS transistor 68 is connected commonly to the other end of the MOS transistor 67, and the other end is supplied with a voltage VREG. One end of the MOS transistor 69 is connected to the gate.

One end of the MOS transistor 69 is connected to the gate of the MOS transistor 68, and the other end is connected to a node N1a. The gate is supplied with a signal DTG.

A DDC is configured with the MOS transistors 68 and 69.

One end of the MOS transistor 70 is connected to the node N1a, and the other end is connected to the node N4. The gate is supplied with a signal BLC.

One end of the MOS transistor 71 is connected to the node N1a, and the other end is connected to a node N1b. The gate is supplied with a signal EQ1.

The input port of the inverter 72 is connected to the node N1b, and the output port thereof is connected to the node N1a.

The input port of the inverter 73 is connected to the node N1a, and the output port thereof is connected to the node N1b.

A PDC is configured with the MOS transistors 71 and the inverters 72 and 73.

One end of the MOS transistor 74 is connected to one end of the MOS transistor 75, and the other end is grounded. The gate is supplied with a signal CHK1.

One end of the MOS transistor 75 is connected to one end of the MOS transistor 74, and the other end is connected to COMi. The node N1b is connected to the gate.

One end of the MOS transistor 76 is connected to the node N1a, and the other end is grounded. The gate is supplied with a signal PRST.

The MOS transistor 76 has a function of resetting retention data of the PDC.

In addition, one end of the MOS transistor 77 is connected to the node N1a, and the other end is connected to a signal line IOn. The gate is supplied with a signal CSLi.

One end of the MOS transistor 78 is connected to the node N1b, and the other end is connected to a signal line IO. The gate is supplied with the signal CSLi.

When these MOS transistors 77 and 78 are turned on, the retention data of the PDC is output to the signal line IO and the signal line IOn. Meanwhile, inverse data of the signal line IO is transferred to the signal line IOn.

1.5 Column Decoder 14

Referring back to FIG. 1, peripheral circuits will be described. The column decoder 14 decodes a column address signal which is input from the address and command register 17, and selects the column direction of the memory cell array 11.

1.6 Input and Output Circuit 16

The input and output circuit 16 receives the command CMD, the address ADD, and data from an external host device (not shown) through the memory controller 2, supplies the command and the address to the address and command register 17, receives data from the sense amplifier 13, and outputs the data to the memory controller (host device).

1.7 Address and Command Register 17

The address and command register 17 temporarily holds the command CMD and the address ADD which are supplied from the input and output circuit 16, and next supplies the command CMD to the control circuit 15 and supplies the address ADD to the row decoder 12, the column decoder 14, and the selector 151.

1.8 Internal Voltage Generation Circuit 18

The internal voltage generation circuit 18 generates a predetermined voltage in a reading operation and a write operation based on the control of the control circuit 15.

In the reading operation, the internal voltage generation circuit 18 generates the voltage VCGR and the voltage VREAD.

The internal voltage generation circuit 18 supplies the voltage VCGR to the select word line WL, and next supplies the voltage VREAD to the non-selected word line WL.

The voltage VCGR is a voltage which is supplied to the select word line WL. In addition, the voltage VREAD is a voltage for turning on the memory cell MC regardless of retention data.

In the write operation, the internal voltage generation circuit 18 generates the voltage VPGM, the voltage VPASS, and a voltage VISO.

The internal voltage generation circuit 18 supplies the voltage VPGM to the selected word line WL, and supplies any of the voltage VPASS and the voltage VISO to the non-select word line WL.

Meanwhile, the voltage VPGM is a voltage having a magnitude of such an extent as to inject charge to a charge storage layer, described later, included in the memory cell MC, and to transition the threshold of the memory cell MC to another level.

In addition, the voltage VPASS is a voltage which is applied to the non-selected word line WL in the selected memory string MS, and is optimized so that data writing is not performed.

Further, the voltage VISO is a voltage for electrically cutting off a successive channel within the memory string MS, and has a function of boosting a channel.

### 2. With Respect to Cross-Sectional View of Plane P

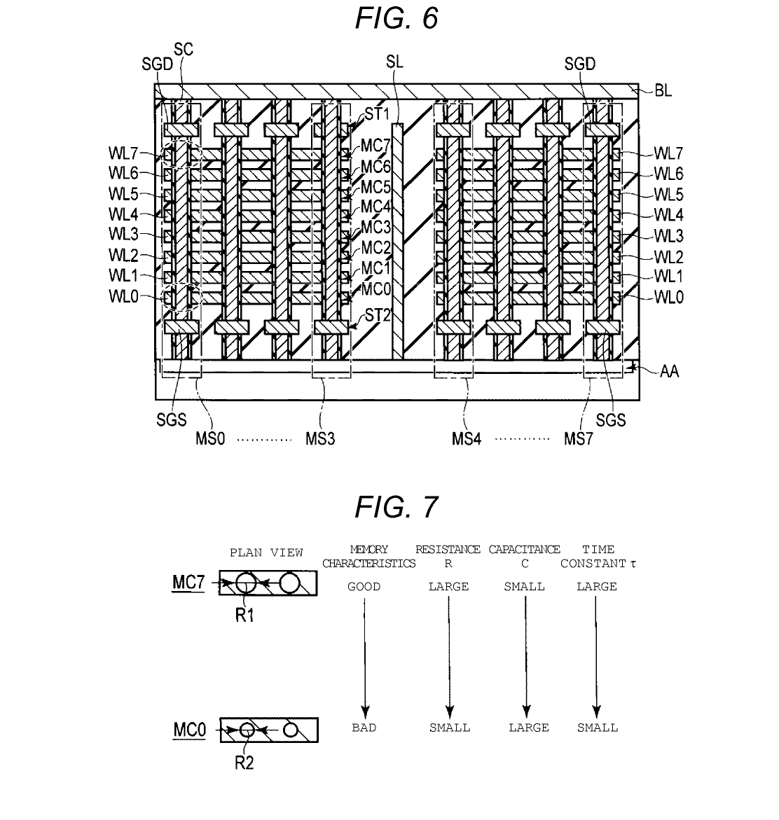

FIG. 6 is a cross-sectional view illustrating a portion of a region of the memory cell array 11 according to the present embodiment.

Each of the memory strings MS (MS0 to MS7 in the drawing) as shown in FIG. 6 includes a selection transistor ST2, dummy memory cells MCDS0 and MCDS1 (not shown), a memory cell MC0-7, dummy memory cells MCDD0 and MCDD1 (not shown), and a selection transistor ST1 which are formed on CPWELL in order from below, and a semiconductor layer SC0 and a source line SL which are formed in a direction normal to the CPWELL.

Meanwhile, the selection transistors ST1 and ST2 are formed at a position where a signal line functioning as a selection gate line SGS and the semiconductor layer SC intersect each other.

In addition, the memory cell MC is formed at an intersection point between a signal line functioning as the word line WL and the semiconductor layer SC.

In the non-volatile semiconductor memory device according to the present embodiment, signal lines SGD and signal lines SGS are respectively adjacent to the memory strings MS.

Further, the source line SL formed in the normal direction is formed between the memory string MS3 and the memory string MS4.

The source line SL may be formed like, for example, a wall shape that extends in the depth of the plane of paper, and may be formed in a strut shape similarly to the semiconductor layer SC.

In such a stacked memory cell MC, the diameter of the semiconductor layer SC in a lower layer portion is smaller than the diameter thereof in an upper layer portion.

This is because the semiconductor layer SC is formed in a taper shape.

For example, as shown in FIG. 7, the diameter of the semiconductor layer SC in an upper layer (for example, memory cell MC7) is R1, but the diameter of the semiconductor layer SC in a lower layer (for example, memory cell MC0) is R2 (<R1).

For this reason, the resistance value R of the word line WL transitions from “high” to “low” from the upper layer toward the lower layer, and the capacitance C of the word line WL transitions from “low” to “high” from the upper layer toward the lower layer.

Therefore, the time constant τ=RC of the word line WL has a tendency to transition from “high” to “low” from the upper layer toward the lower layer.

In addition, the retention characteristics of the memory cell MC have a tendency to deteriorate from the upper layer toward the lower layer of the semiconductor layer SC. This is because, the semiconductor layer SC is formed in a taper shape, and it is considered that the concentration of an electric field occurs, when being left behind, due to the small diameter of the lower-layer memory cell MC as described above.

Meanwhile, the lower layer as used herein refers to any one of the word lines WL0 to WL3, and the upper layer as used herein refers to any one of the word lines WL4 to WL7. Meanwhile, R1 and R2 are relative values of the upper layer and the lower layer.

### 4. With Respect to Transfer Timing of Voltage VCGR

As described above, the time constants τ are different from each other in the upper layer and the lower layer of the word line WL. For this reason, a difference between stabilization times until charge stored in the word line WL flows out and a voltage reaches a desired recovery voltage (for example, initial value (0 V)) occurs in the upper layer and the lower layer.

As a result, timings at which the voltage VCGR is able to be supplied are different from each other in accordance with whether the selected word line WL is located at the upper layer or the lower layer.

The timing used before conforms to a timing at which the voltage VCGR is supplied slowly, that is, to a timing at which the voltage VCGR is supplied to the upper-layer word line WL. However, in the present embodiment, when the reading operation may be executed early, the reading operation is started without waiting for a timing at which the voltage VCGR is supplied to the upper-layer word line WL.

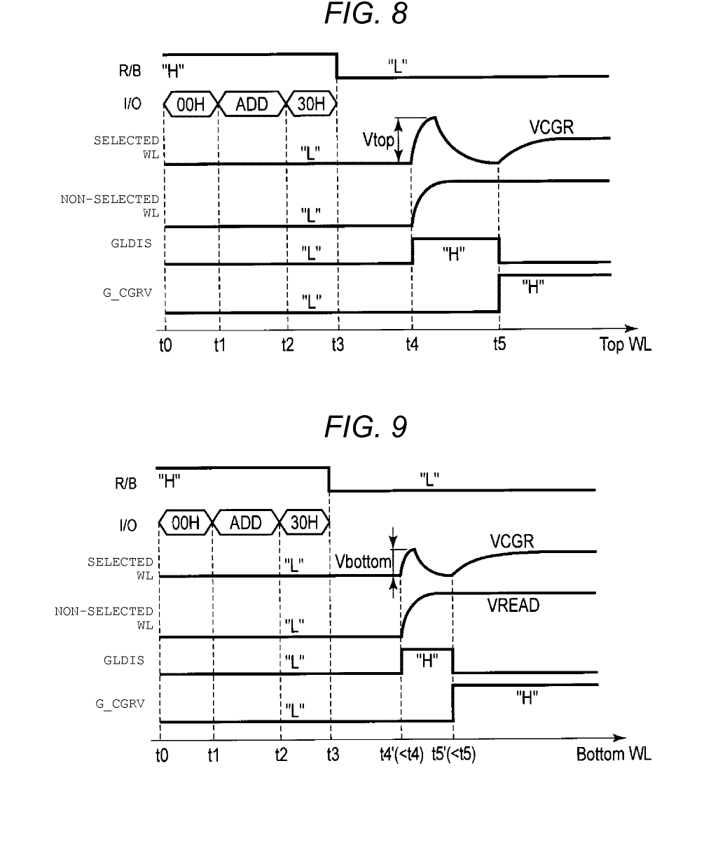

This status will be described with reference to FIGS. 8 and 9.

4-1 Upper-Layer Memory Cell MC

As shown in FIG. 8, the vertical axis represents an R/B signal, an I/O signal, a selected word line WL, a non-selected word line WL, a signal GLDIS, and a signal G_CGRV, and the horizontal axis represents a time.

When the command OOH is received from a host device at time t0, the address ADD received at time t2, and the command 30H received at time t3, the control circuit 15 transitions the R/B signal from former “H” to “L”. That is, the control circuit 15 notifies the host device of a busy state, and executes the reading operation.

At time t4, the control circuit 15 causes the internal voltage generation circuit 18 to supply the voltage VREAD to the non-selected word line WL.

In addition, at the same time, the control circuit 15 sets the voltage level of the signal GLDIS to “H”. Thereby, the selected word line WL is set to the ground potential.

However, the potential of the selected word line WL is boosted due to a rise in the voltage of a peripheral non-selected word line WL.

As described above, since the time constant τ of the word line WL located at the upper layer is large, it takes time until the boosted voltage returns to the ground potential. Here, the time at which the potential of the selected word line WL returns to the initial value (0 V) is set to t5.

The control circuit 15 sets the signal GLDIS to “L” at this timing, that is, time t5, and next sets the voltage level of the signal G_CGRV to “H”.

Thereby, the potential of the selected word line WL is boosted from 0 V to the voltage VCGR, and the reading operation is performed.

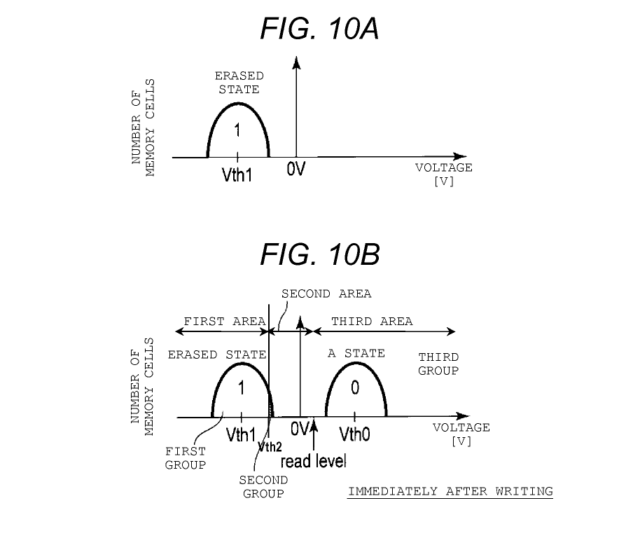

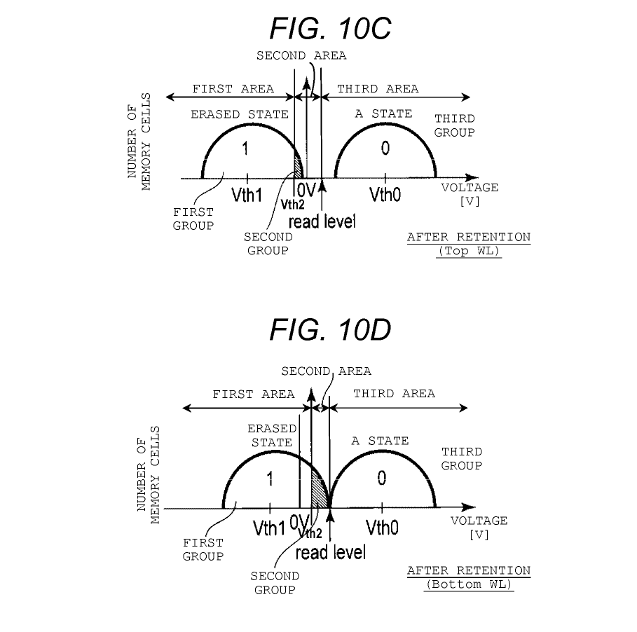

Meanwhile, when the value of the voltage VCGR for determining the threshold distribution of the memory cell MC is the voltage VCGR=Read level shown in FIGS. 10A to 10D, the Read level is supplied to the selected word line WL. Hereinafter, the same description applies to section 4-2.

4-2 Lower-Layer Memory Cell MC

As shown in FIG. 9, the vertical axis represents the R/B signal, the I/O signal, the selected word line WL, the non-selected word line WL, the signal GLDIS, and the signal G_CGRV, and the horizontal axis represents a time. Meanwhile, the operations of FIG. 9 already depicted above will not be described.

Since the potential of the non-selected word line WL is boosted to the voltage VREAD at time t4′, the potential of the selected word line WL is boosted by coupling.

As described above, the time constant τ of the word line WL located at the lower layer is small.

For this reason, the time until the boosted voltage returns to the ground potential is shorter than that in the upper-layer word line WL. Here, the time at which the potential of the selected word line WL returns to the initial value (0 V) is set to t5′ (<t5).

The control circuit 15 sets the signal GLDIS to “L” at this timing, that is, time t5′, and sets the voltage level of the signal G_CGRV to “H”.

Thereby, the potential of the selected word line WL is boosted to the voltage VCGR earlier by (t5-t5′) than time t5 shown in FIG. 8.

### Effect of First Embodiment

In the non-volatile semiconductor memory device according to the first embodiment, it is possible to obtain an effect of (1).

(1) In the word line (lower-layer word line in the present embodiment) having an early setup time during reading, it is possible to start the reading operation earlier.

The timing used before conforms to a timing at which the voltage VCGR is supplied to the lower-layer and upper-layer selected word lines WL. That is, the timing of the voltage VCGR which is supplied to the lower-layer word line WL is necessarily set to a timing at which the voltage VCGR is supplied to the upper-layer word line WL. In this manner, reading times Tr are the same as each other both in the upper layer and in the lower layer.

On the other hand, in the first embodiment, when the potential of the lower-layer selected word line WL returns to the ground potential as described above, reading is performed immediately after that. Thereby, the reading operation may be terminated early in the lower-layer word line WL. In addition, since the reading operation may be terminated early in the lower-layer word line WL, it is possible to reduce the amount of power consumption.

### First Modification Example

Next, a non-volatile semiconductor memory device according to a modification example of the first embodiment (hereinafter, referred to as the first modification example) will be described.

According to the first embodiment, a situation occurs in which the reading time Tr of the upper-layer word line WL becomes longer than in a case where the lower-layer word line WL is selected.

Consequently, in the first modification example, the delay time of the upper-layer word line with respect to the lower-layer word line WL is compensated for by controlling a sense timing for the memory cell MC corresponding to the upper-layer word line WL (reducing the number of times to change the voltage level of the signal STB). That is, a difference occurs in the reading time in accordance with the layer of the word line, but the number of times of reading for the memory cell having high reliability is reduced because of the reliability of the memory cell.

First, the threshold distribution of the memory cell MC will be described with reference to FIGS. 10A to 10D. The memory cell MC in the present embodiment may hold any one of pieces of binary (1-bit) data, for example. Two levels are an “E” level and an “A” level in order increasing voltage.

As depicted in FIG. 10A, the “E” level is called an erased state, and refers to a state where charge is not present in the charge storage layer. When charge is stored in the charge storage layer, the threshold distribution rises from the “E” level to the “A” level. Meanwhile, charge is not necessarily zero in the “E” level.

The memory cell MC of the erased state is specified as “1” data, and the memory cell MC having the threshold distribution of the “A” level is specified as “0” data.

Here, as shown in FIGS. 10B to 10D, the “E” level and the “A” level are classified into first to third groups. Specifically, in the erased state, a set of the memory cell MC having the threshold distribution of a first area is classified into the first group, and a set of the memory cell MC having the threshold distribution of a second area is classified into the second group. In addition, a set of the memory cell MC having the threshold distribution of a third area is set to the third group. The first area is an area where a threshold voltage of the memory cell is lower than Vth2 in FIG. 10B. The second area is an area where a threshold voltage of the memory cell is lower than the read level and higher than the Vth2 in FIG. 10B. The third area is an area where a threshold voltage of the memory cell is higher than the read level in FIG. 10B.

Here, the memory cell MC belonging to the shaded second group indicates a memory cell MC in which erroneous reading is performed. Meanwhile, since a cell current flowing through a memory cell varies with a temperature, a boundary between the first area and the second area varies with a temperature or the like during reading.

The retention characteristics of the memory cell MC will be described using threshold distributions shown in FIGS. 10B to 10D. The retention characteristics refer to data retention characteristics when data is written in the memory cell and then left behind for a long period of time.

FIG. 10B is the threshold distribution of any of the upper-layer and lower-layer memory cells MC immediately after writing.

FIG. 10C is the threshold distribution of a memory cell MC having a certain data retention period, that is, a memory cell MC located at the upper layer.

Further, FIG. 10D is the threshold distribution of a memory cell MC having a certain data retention period, that is, a memory cell MC located at the lower layer.

For example, as shown in FIG. 10B, the threshold distribution immediately after writing is present in either the erased state or the A state in any of the upper layer and the lower layer, and each distribution is narrow in width.

However, a change occurs in the threshold distribution with the lapse of time, and whether the level of the broadening of the threshold distribution is within the range correctable through ECC correction is a problem.

For example, when focused on the retention characteristics of the memory cell MC7 surrounded by a circle in FIG. 6, as shown in FIG. 10C, the distribution of the “E” state and the “A” state is wider than that in FIG. 10B, but the distribution of the memory cell MC7 is within an ECC correction capability range because of the small number of memory cells MC in the second group.

Therefore, for example, even when erroneous reading is performed on the second group, accurate reading may be made by ECC (error correcting code).

On the other hand, as shown in FIG. 10D, when focused on the retention characteristics of the memory cell MC0, the threshold distributions of the both are wider than that in FIG. 10B.

For this reason, the number of memory cells MC0 belonging to the second group is larger than that of the memory cells MC7, and ECC correction capability is exceeded.

Therefore, as a result, correct reading is not able to be performed on one-time read data.

The reason for not being able to perform first correct reading is that the potential of the source line SL is boosted due to the inflow of a cell current of the memory cell MC belonging to the first group, as a result of which the gate-source voltage difference of the memory cell MC becomes smaller, and a reading margin becomes smaller.

This is caused by the deviation of an on-state threshold distribution. That is, the threshold distribution of the memory cell MC in the erased state deviates, and as a result, a voltage indicated by, for example, the read level in the drawing is supplied to the gate with respect to the memory cell MC shifted to the positive side.

Then, the memory cell MC which is distributed in the first group is turned on, and thus a large amount of cell current flows into the source line SL. The potential of the source line SL is then boosted.

Then, for example, regarding the memory cell MC7 having good retention characteristics of FIG. 10C, a reading margin is sufficiently prepared, and thus one reading operation is enough for reading. However, regarding the memory cell MC0 having the retention characteristics of FIG. 10D, since a threshold is shifted to the positive side and then the potential of the source line SL is boosted, a reading margin becomes smaller. Thus, in FIG. 10D, there is the high possibility of the first reading being incorrect, and thus two reading operations are required.

The reason is because, in second reading, regarding the memory cells MC (for example, half of memory cells MC) in which data is successfully read in a first reading operation, more reading operations are not performed, and thus these memory cells block a current flowing into the source line SL, and so a current rise in the source line SL is small. In other words, the reading margin becomes larger.

Therefore, in the second read, since a gate-source potential difference may be sufficiently obtained, it is possible to execute accurate reading in the read level as in FIG. 10D.

In this manner, the control circuit 15 according to the first modification example controls the read timing T in accordance with the position (determined based on the acquired word line WL address) of the memory cell MC to be read.

1. Reading Operation

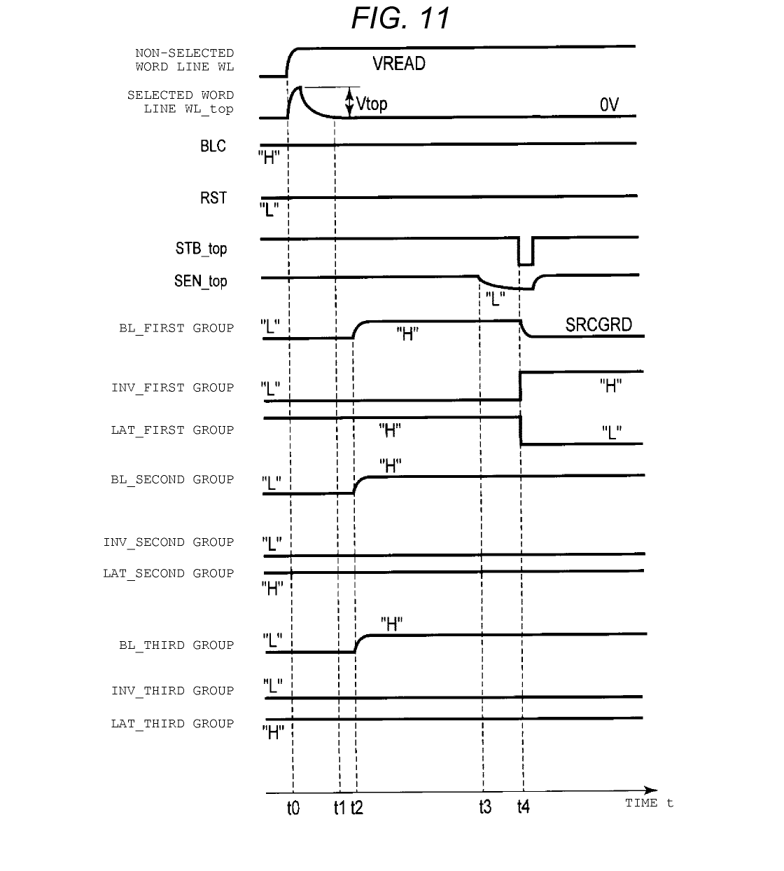

Next, the reading operation of the non-volatile semiconductor memory device according to the present embodiment will be described with reference to FIGS. 11 and. 12.

1.1 Readout of Upper-Layer Word Line WL

FIG. 11 is a timing diagram illustrating the transition of the voltage level of each signal when the reading operation is performed on the upper-layer word line WL. The vertical axis represents word lines WL (non-selected, selected top, signal BLC, signal RST, signal STB_top, signal SEN_top, bit line BL_first group, signal INV_first group, signal LAT_first group, bit line BL_second group, signal INV_second group, signal LAT_second group, bit line BL_third group, signal INV_third group, and signal LAT_third group), and the horizontal axis represents time t.

Meanwhile, “first group”, “second group” and “third group” indicated in the timing diagram are groups classified according to first, second, and third areas described above. Meanwhile, a boundary between the areas in FIGS. 10A to 10D is an example. As described above, the boundary fluctuates in accordance with a temperature or the like, and thus is not fixed.

In addition, the magnitude of the voltage level of each signal and a timing at which the voltage level is supplied are controlled by the control circuit 15, and particularly, the timing T1 is adopted as the timing.

Hereinafter, operations will be described.

As described above, when a command and an address (not shown) are received, the control circuit 15 controls the internal voltage generation circuit 18 so as to supply the voltage VREAD to the non-selected word line WL at time t0. Then, the potential of the selected word line WL is boosted from 0 V by coupling, along with a rise in the voltage of the non-selected word line WL. Specifically, the potential is boosted to a voltage V_top, and then returns to the initial value (0 V) at time t2.

Thereafter, at time t2, the control circuit 15 supplies, for example, the voltage VDD to the bit line BL.

With Respect to First Group

The memory cell MC belonging to the first group is turned on by supplying the voltage VCGR=Read level shown in FIGS. 10A to 10D, and thus the memory string MS allows for the electrical conduction as a result.

Here, since the signal BLC is set to “H”, the SEN node begins to discharge at time t3, and the MOS transistor 45 is turned on.

Thereafter, the control circuit 15 sets the voltage level of the signal STB_bottom to “L” at time t4 (timing T1).

Thereby, since each of the MOS transistors 54 and 45 is turned on, the voltage level of node N1 (INV) is set to “H (voltage VDD)” at the same time t4 (voltage level of LAT is set to “L”). Thereby, data is stored in the SA Latch.

In addition, the MOS transistor 41 is turned on in accordance with the value of the node N1, the potential of the bit line BL_first group transitions to SRCGND (for example, 0 V) at the same time t4.

With Respect to Second Group

The memory cell MC belonging to the second group is to be turned on at the Read level shown in FIGS. 10A to 10D. However, as described above, when the amount of current flowing in the memory cell MC of the first group is large, the potential of the source line SL has a tendency to be boosted due to the amount of current flowing into the source line SL.

For this reason, the memory cell MC belonging to the second group is not turned on, and is determined as “1” data.

As shown in FIG. 11, the voltage level of the bit line BL (in the drawing, BL_second group) attempted to read data from the memory cell MC belonging to the second group is maintained at “H”, and the voltage level of corresponding INV also remains “L”. That is, at this point in time, erroneous reading is performed.

However, since the number of memory cells of the second group in FIG. 10B is small, the ECC correction may be performed, and thus the event of the erroneous reading may be ignored.

With Respect to Third Group

The memory cell MC belonging to the third group is turned off at the voltage VCGR=Read level. For this reason, as shown in FIG. 11, the voltage level of the bit line BL is maintained at a “H” level after time t2. For this reason, the voltage levels INV and LAT corresponding to the memory cell MC of the third group are also maintained at a constant value.

1.2 Readout of Lower-Layer Word Line WL

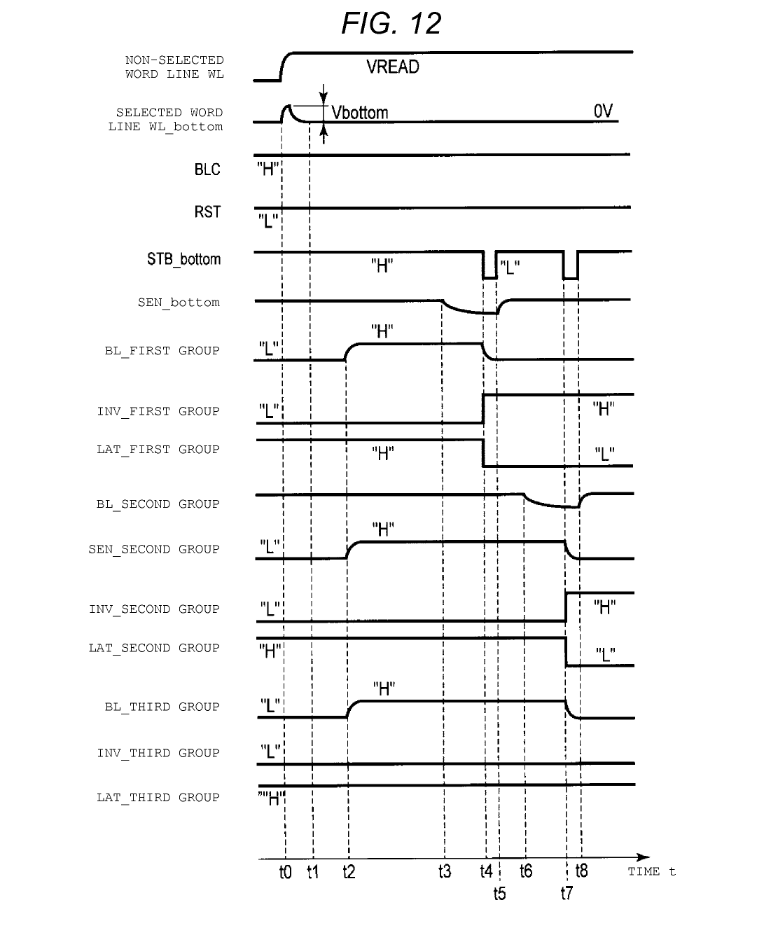

FIG. 12 is a timing diagram illustrating the transition of the voltage level of each signal when reading is performed on the lower-layer word line WL. The vertical axis represents word line WL (non-selected, selected bottom), signal BLC, signal RST, signal STB_bottom, signal SEN_bottom, bit line BL_first group, signal INV_first group, signal LAT_first group, bit line BL_second group, signal INV_second group, signal LAT_second group, bit line BL_third group, signal INV_third group, signal LAT_third group, and the horizontal axis represents time t.

Hereinafter, only those operations different from those in FIG. 11 will be described.

In addition, the magnitude of the voltage level of each signal and a timing at which the voltage level is supplied are controlled by the control circuit 15, and particularly, the timing T2 is adopted as the timing.

With Respect to First Group

Since the memory cell MC belonging to the first group is turned on at the voltage VCGR=Read level, the memory string MS allows for the electrical conduction.

Here, since the signal BLC is set to “H”, the SEN node begins to discharge at time t3, and the MOS transistor 45 is turned on.

Thereafter, the control circuit 15 sets the voltage level of the signal STB_bottom to “L” at time t4 (first timing T2).

Thereby, since each of the MOS transistors 54 and 45 is turned on, the voltage level of node N1 (INV) is set to “H (voltage VDD)” at the same time t4 (voltage level of LAT is set to “L”).

Therefore, the MOS transistor 41 is turned on, the potential of the bit line BL_first group transitions SRCGND (for example, 0 V) at the same time t4, and reading is completed.

In this manner, similarly to FIG. 11, the second reading may be omitted with respect to the memory cell MC belonging to the first group.

In addition, the control circuit 15 performs control so that the sense amplifier 13 corresponding to the memory cells MC in the first group does not enter the next reading operation. Thereby, in the next reading operation, the amount of current flowing into the source line SL is reduced.

With Respect to Second Group

When the reading operation is executed on the lower-layer word line WL, it is necessary to improve the reliability of read data. For this reason, a second reading operation is executed on the same memory cell MC by the control circuit 15.

In the second reading operation, when the row decoder 12 supplies the voltage VCGR=Read level to the word line WL, the memory cell MC located at the second group is turned on. This is because, as described above, the amount of current flowing into the source line SL is reduced as compared to the first reading operation.

Next, at time t6, the SEN node (denoted by SEN second group) begins to discharge, and the MOS transistor 45 is turned on.

Thereafter, the control circuit 15 sets the voltage level of the signal STB_bottom to “L” at time t7 (second timing T2).

Thereby, since each of the MOS transistors 54 and 45 is turned on, the voltage level of node N1 (INV) is set to “H (voltage VDD)” at the same time t7 (voltage level of LAT is set to “L”).

Therefore, the MOS transistor 41 is turned on, the potential of the bit line BL_second group transitions SRCGND (for example, 0 V) at the same time t7, and the reading operation for the memory cell MC belonging to the second group is completed.

### Effect According to First Modification Example

The non-volatile semiconductor memory device according to the first modification example may further obtain an effect of (2).

(2) It is possible to shorten a reading time.

In the non-volatile semiconductor memory device according to the first modification example, when the upper-layer word line WL is selected, the sensing timing T is controlled in consideration of the reliability (retention characteristics) of a corresponding memory cell MC, and thus the number of times of reading is set to one.

As described above, this is because there is the high possibility of being able to be corrected by the ECC correction, for example, even when erroneous reading is present in the memory cell MC, and thus the number of times of reading may be set to one.

Thereby, the timing at which the reading operation is started with respect to the upper-layer word line WL is delayed as compared to the lower-layer word line WL, but it is possible to eliminate the delay by shortening the number of times of the subsequent sense operation.

According to the non-volatile semiconductor memory device of the present embodiment, it is possible to realize a high-speed reading operation.

In order to make the effect of the present embodiment easier to understand, a comparative example is illustrated and described. Meanwhile, in the comparative example, the same components are denoted by the same reference numerals and signs.

In the comparative example, a reading operation for turning on the signal STB two times irrespective of the position of the selected word line WL is adopted.

Then, in a upper-layer word line WL having a large time constant τ, a read timing is slower than in the lower-layer word line, and thus a timing at which data is fetched to the SA Latch within the sense amplifier 13 is also slower in the upper-layer word line WL than in the lower-layer word line.

That is, the reading time Tr required for the upper-layer word line WL becomes longer than that in the lower-layer word line. Therefore, when the number of times of reading for the upper-layer word line WL is large, the time of the entire reading operation is greatly lengthened.

On the other hand, in the non-volatile semiconductor memory device according to the present embodiment, when the reading operation is executed on the upper-layer word line WL, the signal STB is turned on just once. Therefore, for example, even when a timing at which the voltage VCGR is supplied is delayed, it is possible to eliminate the amount of the delay.

### Second Modification Example

Next, a non-volatile semiconductor memory device according to a modification example of the first embodiment (hereinafter, referred to as the second modification example) will be described.

In the first embodiment, during reading of the upper-layer word line WL having good retention characteristics, the entire reading time is shortened by controlling the timing T at which the voltage level of the signal STB is set to “L”, but here, the reading time is shortened by another method.

In the second modification example, the rate of rise in the voltage applied to the non-selected word line WL is increased, and the reading speed is improved. The rate of rise in the voltage applied to the non-selected word line WL is controlled by increasing a rate of rise in the voltage G_USEL in FIG. 2.

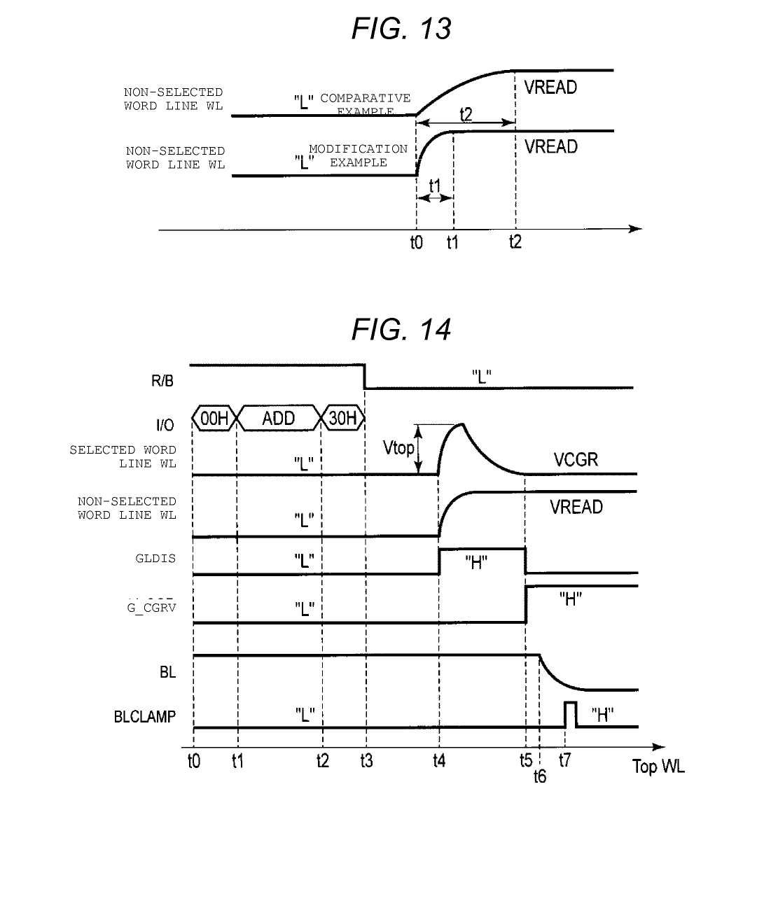

As shown in FIG. 13, a voltage which is supplied to the non-selected word line WL according to the modification example rises at time t0, and then reaches the voltage VREAD at time t1.

On the other hand, a voltage which is supplied to the non-selected word line WL according to the comparative example rises at time t0. Thereafter, the voltage reaches the voltage VREAD at time t2 (>t1).

In this manner, according to the non-volatile semiconductor memory device of the modification example, since the rise time of the non-selected word line WL may be shortened, it is possible to shorten a time required for reading.

Meanwhile, in the modification example, a combination of the operation of the first embodiment may be made. That is, when the rise time of the non-selected word line WL is shortened, and reading for the upper-layer word line WL is performed, the number of times which is set to “L” may be set to one by controlling the timing T at which the voltage level of the signal STB is set to “L”. Thereby, it is possible to further shorten a time required for the reading operation.

### Third Modification Example

In a non-volatile semiconductor memory device according to a modification example of the first embodiment (hereinafter, referred to as the third modification example), the sense amplifier 13 described in 1.4.2 is configured such that a charge share timing is made variable in accordance with whether the word line WL to be read is located at the upper layer or the lower layer.

Specifically, a timing at which the voltage level of the signal BLCLAMP described later is set to “H” is made variable in the upper-layer word line WL and the lower-layer word line WL.

1. Reading Operation

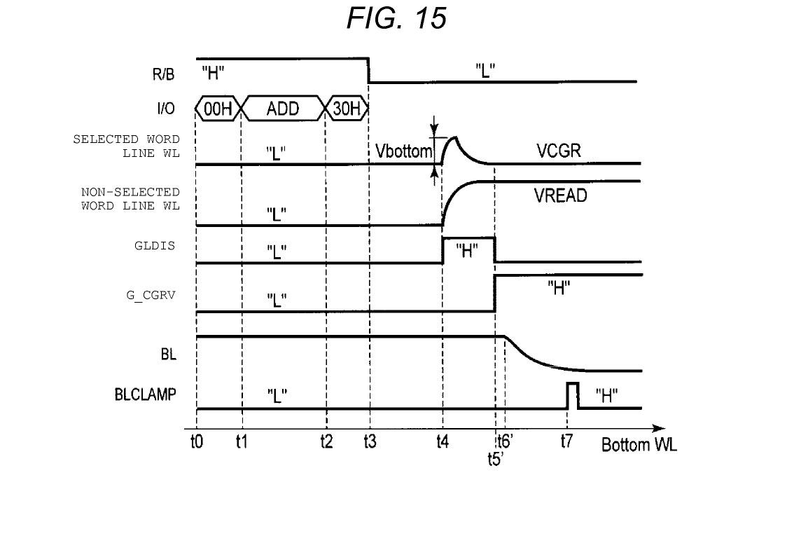

Next, a reading operation according to the third modification example will be described with reference to FIGS. 14 and 15.

FIGS. 14 and 15 are timing diagrams illustrating the transition of the voltage level of each signal. The vertical axis represents R/B, the I/O signal, the selected word line WL, the non-selected word line WL, the signal GLDIS, the signal G_CGRV, the bit line BL, and the signal BLCLAMP, and the horizontal axis represents time t.

Meanwhile, the same operations as those in the first embodiment are not described, and the retention data of the memory cell MC to be read is “1”, that is, a threshold is distributed at the erase level.

1-1. FIG. 14: Upper-Layer Word Line WL

When the control circuit 15 sets the voltage level of the signal GLDIS to “H” at time t4, the boosted potential of the selected word line WL is settled down to the initial value (0 V) at time t5.

In addition, as described above, since the retention data of the memory cell MC to be read is “1”, and the non-selected word line WL is supplied with the voltage VREAD after time t4, the memory string MS enters an electrical conduction state.

Thereafter, the control circuit 15 turns on the selection transistor ST2 (not shown), and discharges the bit line BL from the drain side to the source line SL. Thereby, the potential of the bit line BL drops at time t6.

The memory cell MC corresponding to the upper-layer word line WL has a tendency to cause a large amount of cell current to flow due to good memory characteristics.

That is, as shown in FIG. 14, the voltage of the bit line BL drops drastically after time t6.

Consequently, while predicting the characteristics, the control circuit 15 sets the voltage level of BLCLAMP to “H” at time t7 after that, and executes charge share by electrically connecting the bit line BL and the sense amplifier 13.

That is, even when the time constant τ is large and thus the reading operation is delayed, the discharging of the bit line BL is fast, and the retention characteristics of the memory cell MC is good, whereby the control circuit 15 may execute charge share on the fast discharging of the bit line BL.

In this manner, the reading operation for the upper-layer word line WL may prevent the rate-limitation of the reading time of the entire non-volatile semiconductor memory device.

1-2. FIG. 15: Lower-Layer Word Line WL

When the control circuit 15 sets the voltage level of the signal GLDIS to “H” at time t5, the boosted potential of the selected word line WL is settled down to the initial value (0 V) at time t6′ (<t6).

Thereafter, the control circuit 15 turns on the selection transistor ST2 (not shown), and discharges the bit line BL from the drain side to the source line SL at time t7′ (<t7), whereby the potential of the bit line BL drops.

The memory cell MC corresponding to the lower-layer word line WL has a tendency to cause a smaller amount of the cell current than that in FIG. 14 to flow due to a tendency for the memory characteristics to deteriorate.

That is, since the amount of charge falling out of the bit line BL per unit time is small, the potential drops gradually.

The control circuit 15 predicts this point, and sets the voltage level of the signal BLCLAMP to “H” at a point in time when the potential of the bit line BL drops sufficiently, that is, time t7.

### Second Embodiment

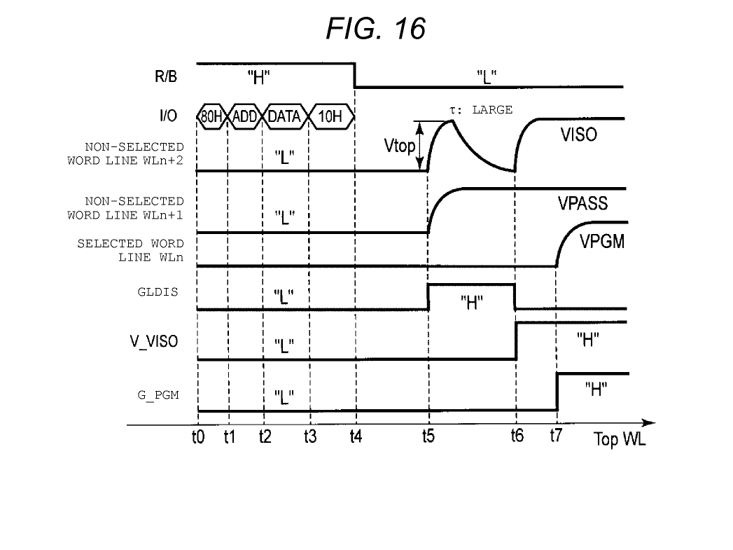

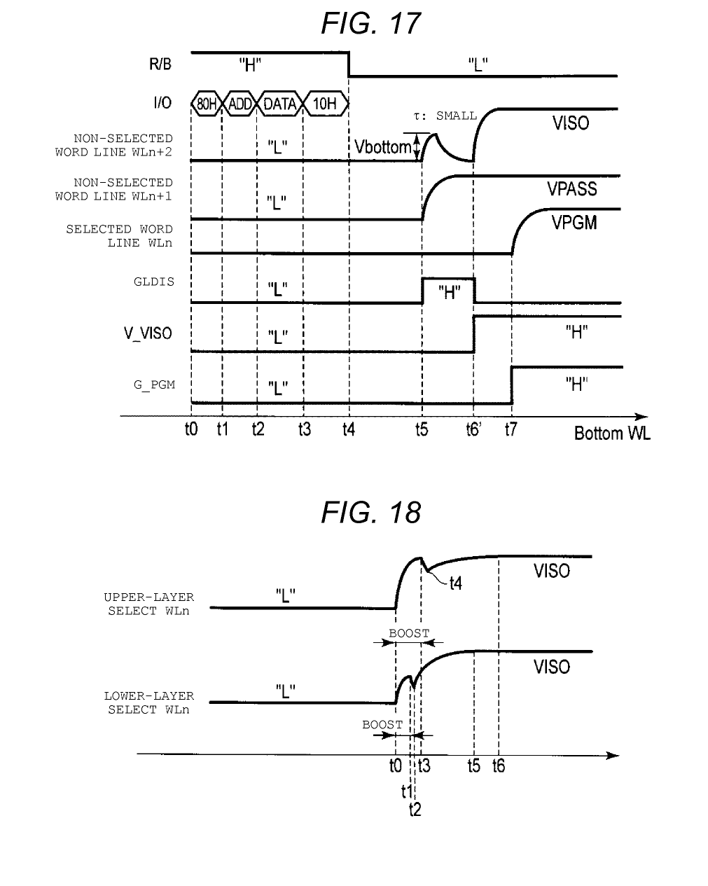

Next, a non-volatile semiconductor memory device according to a second embodiment will be described with reference to FIGS. 16 and 17. In the second embodiment, attention is focused on the write operation of the sense amplifier 13.

The sense amplifier 13 according to the second embodiment has the same configuration as that described in the first embodiment, and thus the description thereof will not be given.

Meanwhile, in the following write operation, any of the sense amplifiers 13 may be adopted.

1. With Respect to Write Operation

First, the selected word line WL to be written is set to an n-th (n is a positive integer) word line WL.

1.1 Writing of Upper-Layer Word Line WL

As shown in FIG. 16, the control circuit 15 receives a write command 80H, an address ADD, data, and a command 10H from a host device through the memory controller 2 for a period of time t0 to time t4.

The control circuit 15 then sets the R/B signal to “L” at time t4, and executes the write operation.

Specifically, the control circuit 15 controls the voltage generation circuit 18 so as to supply the voltage VPASS to, for example, a non-selected word line WLn+1 at time t5.

At this timing, the control circuit 15 sets the voltage level of the signal GLDIS to “H”, but the potential of a non-selected word line WLn+2 is boosted to the voltage Vtop because it is an upper-layer word line WL.

Thereafter, the potential of the non-selected word line WLn+2 returns to the initial value (0 V) at time t6.

In addition, the control circuit 15 sets the voltage level of a signal V_VISO to “H” at time t6. Then, the non-selected word line WLn+2 reaches the voltage VISO.

In this manner, when the write voltage VPGM is supplied to the selected word line WLn by cutting off the current path of the memory string MS, a channel potential is boosted, and writing is executed.

1.2 Writing of Lower-Layer Word Line WL

The same operation as in 1.1 is not described.

As shown in FIG. 17, the control circuit 15 supplies the voltage VPASS to, for example, the non-selected word line WLn+1 at time t4.

Then, the adjacent non-selected word line WLn+2 rises to a voltage Vbottom, but returns to the initial value (0 V) at time t5′ (<t5) by the control circuit 15 setting the voltage level of the signal GLDIS to “H”.

Simultaneously, the control circuit 15 sets the voltage level of the signal V_ISO to “H”.

Then, the potential of the non-selected word line WLn+2 becomes the voltage VISO at time t5′.

In this manner, by cutting off the current path of the memory string MS, the control circuit 15 supplies the write voltage VPGM to the selected word line WLn, boosts the channel potential, and executes writing.

### Fourth Modification Example

Next, a non-volatile semiconductor memory device according to a modification example of the second embodiment (hereinafter, referred to as the fourth modification example) will be described.

In the fourth modification example, a writing time is shortened.

Specifically, charge of the selected word line WLn having a boosted potential begins to discharge, and the time is shortened using the boosted voltage without waiting until the potential returns to the initial value.

As shown in FIG. 18, when the selected word line WLn is located at the upper layer, the time constant τ is large, and thus the potential is boosted at time to. Thereafter, the voltage starts to drop at time t3.

At this timing (time t3), the control circuit 15 sets the voltage level of the signal V_VISO to “H”.

Thereby, the potential of the selected word line WLn is boosted from time t4, and reaches the voltage VISO at time t6.

Simultaneously, when the selected word line WLn is located at the lower layer, the time constant τ is small, and thus the potential is boosted at time t0, and then the voltage starts to drop at time t1.

At this timing (time t1), the control circuit 15 sets the voltage level of the signal V_VISO to “H”.

Thereby, the potential of the selected word line WLn is boosted from time t2, and becomes the voltage VISO at time t3.

Even when the above methods 1 and 2 are used, it is possible to shorten the reading time and the writing time.

Meanwhile, the configuration of the memory cell array 11 may be as disclosed in, for example, U.S. patent application Ser. No. 12/407,403 filed on Mar. 19, 2009, entitled “THREE-DIMENSIONAL STACKED NON-VOLATILE SEMICONDUCTOR MEMORY”. In addition, the configuration may be as disclosed in U.S. patent application Ser. No. 12/406,524 filed on Mar. 18, 2009, entitled “THREE-DIMENSIONAL STACKED NON-VOLATILE SEMICONDUCTOR MEMORY”, U.S. patent application Ser. No. 12/679,991 filed on Mar. 25, 2010, entitled “NON-VOLATILE SEMICONDUCTOR MEMORY DEVICE AND METHOD OF MANUFACTURING THE SAME”, and U.S. patent application Ser. No. 12/532,030 filed on Mar. 23, 2009, entitled “SEMICONDUCTOR MEMORY AND METHOD OF MANUFACTURING THE SAME”. These patent applications are incorporated in this disclosure by reference in their entireties.

Meanwhile, in each of the embodiments,

(1) In a reading operation, a voltage which is applied to a word line selected in the reading operation of an A level is, in the range of, for example, 0 V to 0.55. The voltage may be in any range of 0.1 V to 0.24 V, 0.21 V to 0.31 V, 0.31 V to 0.4 V, 0.4 V to 0.5 V, and 0.5 V to 0.55 V, without being limited thereto.

A voltage which is applied to a word line selected in the reading operation of a B level is in the range of, for example, 1.5 V to 2.3 V. The voltage may be in any range of 1.65 V to 1.8 V, 1.8 V to 1.95 V, 1.95 V to 2.1 V, and 2.1 V to 2.3 V, without being limited thereto.

A voltage which is applied to a word line selected in the reading operation of a C level is in the range of, for example, 3.0 V to 4.0 V. The voltage may be in any of range of 3.0 V to 3.2 V, 3.2 V to 3.4 V, 3.4 V to 3.5 V, 3.5 V to 3.6 V, and 3.6 V to 4.0 V, without being limited thereto.

A time (tR) of the reading operation may be in any range of, for example, 25 μs to 38 μs, 38 μs to 70 μs, and 70 μs to 80 μs.

(2) The write operation includes a program operation and a verify operation as described above. In the write operation, the above voltage may be the following voltage in addition to 15.0 V to 23.0 V stated above.

Specifically, a voltage which is initially applied to the selected word line during a program operation is in the range of, for example, 13.7 V to 14.3 V. The voltage may be in any range of, for example, 13.7 V to 14.0 V and 14.0 V to 14.6 V, without being limited thereto.

A voltage which is initially applied to the selected word line during writing of odd-numbered word lines and a voltage which is initially applied to the selected word line during writing of even-numbered word lines may be changed.

When the program operation is set to an ISPP (Incremental Step Pulse Program) system, a step-up voltage includes, for example, approximately 0.5 V.

In addition, a voltage which is applied to the non-select word line may be the following voltage in addition to 7.0 V to 10.0 V stated above.

Specifically, a voltage which is applied to the non-select word line may be in the range of, for example, 6.0 V to 7.3 V. The voltage may be in the range of, for example, 7.3 V to 8.4 V and may be equal to or lower than 6.0 V, without being limited to this case.

A pass voltage to be applied may be changed in accordance with whether the non-select word line is an odd-numbered word line or an even-numbered word line.

A time (tProg) of the write operation may be in the range of, for example, 1,700 μs to 1,800 μs, 1,800 μs to 1,900 μs, and 1,900 μs to 2,000 μs.

(3) In erase operation, a voltage which is initially applied to a well, disposed on the semiconductor substrate, which has a memory cell disposed thereon is in the range of, for example, 12 V to 13.6 V. The voltage may be in any range of, for example, 13.6 V to 14.8 V, 14.8 V to 19.0 V, 19.0 V to 19.8 V, and 19.8 V to 21 V, without being limited to this case.

The time (tErase) of the erase operation may be in the range of, for example, 3,000 μs to 4,000 μs, 4,000 μs to 5,000 μs, and 4,000 μs to 9,000 μs.

(4) The structure of the memory cell includes a charge storage layer which is disposed on a semiconductor substrate (silicon substrate) through a tunnel insulating film having a thickness of 4 nm to 10 nm. This charge storage film may be formed to have a stacked structure of an insulating film such as a SiN film or a SiON film having a thickness of 2 nm to 3 nm, and a polysilicon film having a thickness of 3 nm to 8 nm. A metal such as Ru may be added to the polysilicon film. An insulating film is included on the charge storage film. The insulating film includes a silicon oxide film having a thickness of 4 nm to 10 nm which is interposed between a lower-layer High-k film having, for example, a thickness of 3 nm to 10 nm and an upper-layer High-k film having a thickness of 3 nm to 10 nm. Materials of the High-k film include HfO and the like. In addition, the thickness of the silicon oxide film may be made to be larger than the thickness of the High-k film. A control electrode having a thickness of 30 nm to 70 nm is formed on the insulating film through a film having a thickness of 3 nm to 10 nm. Here, the work function adjusting film is, for example, a metal oxide film such as TaO, or a metal nitride film such as TaN. Tungsten (W) or the like may be used in the control electrode.

In addition, air gap may be formed between the memory cells.

Meanwhile, exemplary embodiments described herein are not limited to the above-mentioned embodiments, and may be modified in various forms without departing the spirits of the invention in the implementation phases. Further, the above-mentioned embodiments include exemplary embodiments of various steps, and various embodiments may be derived from an appropriate combination of a plurality of components disclosed. For example, even when any of components are omitted from all the components disclosed in the embodiments, problems described in “Problem that the Invention is to Solve” may be solved, and when effects described in “Advantage of the Invention” are obtained, a configuration having the component omitted therein may be derived as an embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a plurality of memory cells including a first memory cell and a second memory cell stacked above the first memory cell;
a plurality of word lines including first and second word lines connected to first and second memory cells, respectively;
a driver circuit connected to the word lines to supply voltages of different levels to the gates of the memory cells; and
a control circuit configured to control the driver circuit to supply, during a reading operation on a selected memory cell, a first voltage to other, non-selected memory cells at a first timing and a second voltage to the selected memory cell at a second timing that is after a time period after the first timing, wherein
the time period when the first memory cell is the selected memory cell is less than the time period when the second memory cell is the selected memory cell.

2. The device according to claim 1, further comprising:
a bit line connected to the memory cells; and
a sense amplifier configured to perform sensing of the bit line a first number of times when the first memory cell is the selected memory cell and a second number of times when the second memory cell is the selected memory cell, wherein
the first number of times is greater than the second number of times, which is one or more.

3. The device according to claim 1, wherein
the control circuit is configured to control the driver circuit to supply, during a write operation on a selected memory cell, a third voltage to other, non-selected memory cells at a third timing and a fourth voltage to the selected memory cell at a fourth timing that is after a variable time period after the third timing depending on whether the selected memory cell is the first memory cell or the second memory cell.

4. The device according to claim 3, wherein the time interval between the third timing and the fourth timing is shorter when the selected memory cell is the first memory cell than when the selected memory cell is the second memory cell.

5. The device according to claim 3, further comprising:
a bit line connected to the memory cells, wherein
the third timing when the third voltage is applied to the non-selected memory cell, relative to when the bit line is discharged, is earlier when the selected memory cell is the first memory cell than when the selected memory cell is the second memory cell.

6. A method of controlling a non-volatile semiconductor memory device comprising a plurality of memory cells including a first memory cell and a second memory cell stacked above the first memory cell, a plurality of word lines including first and second word lines connected to first and second memory cells, respectively, and a driver circuit connected to the word lines to supply voltages of different levels to the gates of the memory cells, said method comprising:
supplying during a reading operation on a selected memory cell, a first voltage to other, non-selected memory cells at a first timing and a second voltage to the selected memory cell at a second timing that is after a time period after the first timing, wherein
the time period when the first memory cell is the selected memory cell is less than the time period when the second memory cell is the selected memory cell.

7. The method according to claim 6, wherein
the non-volatile semiconductor memory device further comprises a bit line connected to the memory cells, and a sense amplifier configured to perform sensing of the bit line a first number of times when the first memory cell is the selected memory cell and a second number of times when the second memory cell is the selected memory cell, and
the first number of times is greater than the second number of times, which is one or more.

8. The method according to claim 6, further comprising:
supplying during a write operation on a selected memory cell, a third voltage to other, non-selected memory cells at a third timing and a fourth voltage to the selected memory cell at a fourth timing that is after a variable time period after the third timing depending on whether the selected memory cell is the first memory cell or the second memory cell.

9. The method according to claim 8, wherein the time interval between the third timing and the fourth timing is shorter when the selected memory cell is the first memory cell than when the selected memory cell is the second memory cell.

10. The method according to claim 8, wherein wherein
the non-volatile semiconductor memory device further comprises a bit line connected to the memory string, and
the third timing when the third voltage is applied to the non-selected memory cell, relative to when the bit line is discharged, is earlier when the selected memory cell is the first memory cell than when the selected memory cell is the second memory cell.

11. A non-volatile semiconductor memory device comprising:
a plurality of memory cells including a first memory cell and a second memory cell stacked above the first memory cell;
a control circuit configured to apply a first voltage to a gate of the first memory cell from a first timing when the non-volatile semiconductor memory device receives a read command and a first address corresponding to the first memory cell, the control circuit being configured to apply the first voltage to a gate of the second memory cell from a second timing when the non-volatile semiconductor memory device receives a read command and a second address corresponding to the second memory cell, the first timing being different from the second timing.

12. The device according to claim 11, wherein:
the control circuit is configured to apply, during a reading operation on a selected memory cell, a second voltage to other, non-selected memory cells at a third timing and the first voltage to the selected memory cell at a fourth timing that is after a time period after the third timing, wherein
the time period when the first memory cell is the selected memory cell is less than the time period when the second memory cell is the selected memory cell.

13. The device according to claim 11, further comprising:
a driver circuit connected to the gates of the memory cells to apply voltages of different levels to the gates of the memory cells.

14. The device according to claim 11, further comprising:
a bit line connected to the memory cells; and
a sense amplifier configured to perform sensing of the bit line a first number of times when the first memory cell is the selected memory cell and a second number of times when the second memory cell is the selected memory cell, wherein
the first number of times is greater than the second number of times, which is one or more.

15. The device according to claim 11, wherein
the control circuit is configured to apply, during a write operation on a selected memory cell, a fifth voltage to other, non-selected memory cells at a fifth timing and a sixth voltage to the selected memory cell at a sixth timing that is after a variable time period after the fifth timing depending on whether the selected memory cell is the first memory cell or the second memory cell.

16. The device according to claim 15, wherein the time interval between the fifth timing and the sixth timing is shorter when the selected memory cell is the first memory cell than when the selected memory cell is the second memory cell.

17. The device according to claim 15, further comprising:
a bit line connected to the memory cells, wherein
the third timing when the fifth voltage is applied to the non-selected memory cell, relative to when the bit line is discharged, is earlier when the selected memory cell is the first memory cell than when the selected memory cell is the second memory cell.
